(19) United States
(12) Patent Application Publication
(10) Pub. No.: US 2007/0221400 A1
(43) Pub. Date: Sep. 27, 2007

(54) Multilayer interconnection substrate, semiconductor device, and solder resist

(75) Inventors: Mamoru Kurashina, Kawasaki (JP); Daisuke Mizutani, Kawasaki (JP)

Correspondence Address: KRATZ, QUINTOS & HANSON, LLP, 1420 K Street, N.W., Suite 400, WASHINGTON, DC, 20005, US

(73) Assignee: FUJITSU LIMITED, Kawasaki (JP)

(21) Appl. No.: 11/486,061

(22) Filed: Jul. 14, 2006

(30) Foreign Application Priority Data
Mar. 27, 2006 (JP) 2006-086562

(51) Int. Cl. H05K 1/03

(52) U.S. Cl. 174/255

(57) ABSTRACT

A multilayer interconnection substrate includes a resin laminated structure in which plural build-up layers are laminated, each of the plural build-up layers comprising an insulation layer and an interconnection pattern, and first and second solder resist layers provided on a top surface and a bottom surface of the resin laminated structure, wherein each of the first and second solder resist layers includes a glass cloth.

### CROSS-REFERENCE TO RELATED APPLICATION

The present application is based on Japanese priority application No. 2006-086562 filed on Mar. 27, 2006, the entire contents of which are hereby incorporated by reference.

### BACKGROUND OF THE INVENTION

The present invention generally relates to semiconductor devices and more particularly to a resin material and a multilayer interconnection substrate that uses such a resin material.

A high-performance semiconductor device of these days uses a multilayer resin substrate for the package substrate that carries thereon a semiconductor chip.

On the other hand, intense heat generation takes place in the semiconductor chips used in recent high-performance semiconductor devices, and thus, there is a tendency that warp, originating from thermal stress, is caused in the multilayer resin substrate that carries the semiconductor chip thereon. It should be noted that a semiconductor chip has a much larger elastic modulus as compared with the resin substrate.

Thus, when a semiconductor device is mounted upon a circuit substrate via solder bumps, or the like, a large stress is applied to the bump with heat generation of the semiconductor chip, and there is caused a problem that electric and mechanical connection between the semiconductor chip and the package substrate or between the package substrate and the circuit substrate is destroyed or damaged.

In order to suppress such a problem of warp of the package substrate, a multilayer resin substrate of large elastic modulus has been used, wherein the multilayer resin substrate of large elastic modulus has the construction in which a core layer reinforced with glass cloth is disposed in a central part of the multilayer resin substrate.

With the package substrate having such a thick core layer, on the other hand, the thickness of the substrate increases, while this leads to the problem of increase of inductance in the signal path such as a via-plug formed in the substrate. Thereby, there is caused the problem of decrease in transmission rate of electric signals.

Thus, efforts have been made to realize an extremely thin multilayer resin substrate of the thickness of 500 μm or less, by eliminating the core layer from the multilayer of resin substrates.

### REFERENCES

Patent Reference 1 Japanese Laid-Open Patent Application 2000-133683

Patent Reference 2 Japanese Laid-Open Patent Application 11-345898

Patent Reference 3 Japanese Laid-Open Patent Application 9-289269

Patent Reference 4 WO00/49652 Publication Patent Reference 5 Japanese Laid-Open Patent Application 2002-187935

Patent Reference 6 Japanese Laid-Open Patent Application 2001-127095

### SUMMARY OF THE INVENTION

FIG. 1 shows an example of a conventional multilayer resin substrate having a core.

Referring to FIG. 1, there is provided a core part 11C at the central part of a resin substrate 11 such that the core part 11C includes lamination of core layers 11C₁ and 11C₂ each having a thickness of 40-60 μm and formed of a resin layer impregnating a glass cloth 11G, wherein build-up insulation films 11A and 11B carrying thereon interconnection patterns 12A and 12B are formed on the core part 11C. Further, build-up insulation films 11D and 11E carrying thereon interconnection patterns 12C and 12D are formed under the core part 11C.

Further, a through-via 12C is formed so as to penetrate through the core part 11C for connection of the interconnection layer 12A and the interconnection layer 12D.

Further, solder resist films 13A and 13B are formed respectively on the outermost build-up insulation films 11B and 11E, wherein an electrode pad 14A is formed in the solder resist film 13A and an electrode pad 14B is formed in the solder resist film 13B.

On the multilayer resin substrate 11 thus formed, a semiconductor chip 15 is mounted in a face-down state, wherein electrode bumps 16 of the semiconductor chip 15 are connected to corresponding electrode pads 14A. Further, an underfill resin layer 17 fills a gap between the semiconductor chip 15 and the solder resist film 13A.

On the rear side of the resin substrate 11, solder bumps 17 are formed on the electrode pads 14B for mounting the semiconductor device, formed of the semiconductor chip 15 and multilayer resin substrate 11, upon a circuit substrate.

With the multilayer resin substrate 11 having such a core part 11C, however, there are cases in which the total thickness of the substrate including the core layers 11C₁ and 11C₂ exceeds 500 μm. In general, more than one core layer is used, and the whole thickness of that becomes larger than 500 μm. In such a case, the length of the signal path formed of the through-via 12C and extending from the electrode pad 14B to the electrode pad 14A also exceeds 500 μm, and the signal transmitted through such a long signal path experiences delay as a result of increased inductance.

One approach of avoiding this problem would be to eliminate the core part 11C as shown in FIG. 2 and reduce the thickness of the multilayer resin substrate. However, there is caused a decrease of elastic modulus with such a so-called coreless resin substrate, which does not include a core, from the value of 20 GPa corresponding to the case of providing the core part 11C, to 10 GPa or less, and warp or deformation of the substrate noted before becomes a paramount problem. In FIG. 2, it should be noted that those parts explained previously are designated by the same reference numerals and the description thereof are omitted.

In the case the resin substrate carrying a semiconductor chip has caused a warp, large stress is applied to the junction part between the resin substrate and the circuit substrate to which the semiconductor device having the resin substrate is mounted, and there is caused a problem that the junction part is destroyed or damaged.

According to an aspect of the present invention, there is provided a multilayer interconnection substrate, comprising:

a resin laminated structure in which plural build-up layers are laminated, each of said plural build-up layers comprising an insulation layer and an interconnection pattern; and

first and second solder resist layers provided on a top surface and a bottom surface of said resin laminated structure,

wherein each of said first and second solder resist layers includes therein a glass cloth.

In another aspect of the present invention, there is provided a semiconductor device, comprising:

a multilayer interconnection substrate; and

a semiconductor chip mounted upon said multilayer interconnection substrate in a face-down state,

said multilayer interconnection substrate comprising:

a resin laminated structure in which plural build-up layers are laminated, each of said plural build-up layers comprising an insulation layer and an interconnection pattern;

first and second solder resist layers provided on a top surface and a bottom surface of said resin laminated structure, each of said first and second solder resist layers including therein a glass cloth; and

an electrode pad formed to said of said first and second solder resist layers.

In a further aspect of the present invention, there is provided a solder resist, comprising:

a layer having a solder resist resin composition; and

a glass cloth impregnated in said layer of said solder resist resin composition.

According to the present invention, the solder resist film is reinforced mechanically by impregnating a solder resist to a glass cross, and the elastic modulus of the solder resist film is improved. Thus, by disposing such a rigid solder resist film to the front surface and rear surface of a coreless build-up multilayer substrate, the coreless build-up substrate is mechanically reinforced from the front side and rear side, and it becomes possible to decrease the thickness of the substrate while securing sufficient elastic modulus. With this, inductance of the signal path is decreased in the interconnection substrate, and signal delay is suppressed successfully. Thereby, it should be noted that the solder resist film does not constitute a signal path, and thus, increase of thickness of the solder resist film caused by the glass cross included therein does not cause any adversary effect on the electric properties of the interconnection substrate. Because the interconnection substrate has a large elastic modulus in spite of the fact that the thickness thereof is reduced, there is caused little warp or deformation in the interconnection substrate when a semiconductor chip is flip-chip mounted on such an interconnection substrate and the semiconductor chip thus mounted has caused heat generation. Thereby, highly reliable electric and mechanical connection is realized between the semiconductor chip and the interconnection substrate and also between the interconnection substrate and the circuit substrate.

Further, the solder resist film performs also the function of conventional solder resist film such as prevention of solder bridging, reduction of solder pickup, prevention of contamination of the solder pot, protection of the substrate at the time of the assembling, elimination of oxidation or corrosion of the copper interconnection pattern, elimination of electromigration, and the like.

Other objects and further features of the present invention will become apparent from the following detailed description when read in conjunction with the attached drawings.

### BRIEF DESCRIPTION OF THE DRAWINGS

FIG. 1 is a diagram showing the construction of a semiconductor device that uses a multilayer resin substrate having a core according to a related art of the present invention;

FIG. 2 is a diagram showing the construction of a semiconductor device in which the core part is eliminated in the construction of FIG. 1;

FIG. 3 is a diagram showing the construction of a semiconductor device according to an embodiment of the present invention;

FIGS. 4A-4G are diagrams showing the fabrication process of the semiconductor device of FIG. 3.

### DETAILED DESCRIPTION OF THE INVENTION

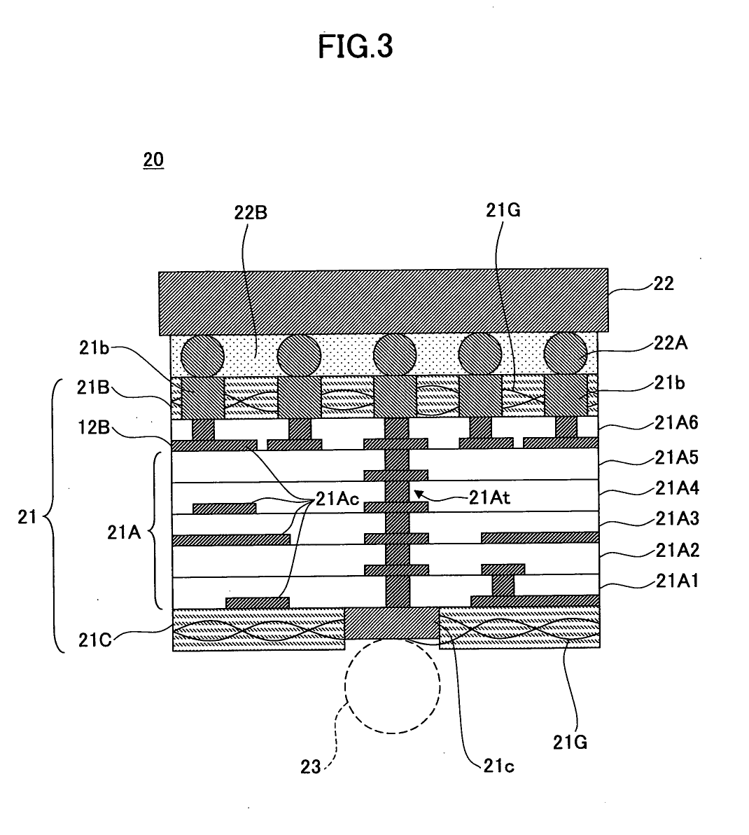

FIG. 3 shows the construction of a semiconductor device 20 according to a first embodiment of the present invention.

Referring to FIG. 3, the semiconductor device 20 is formed of a resin multilayer interconnection substrate 21 and a semiconductor chip 22 flip-chip mounted upon the resin multilayer interconnection substrate 21 by solder bumps 22A, wherein the resin multilayer interconnection substrate 21 is formed of a resin build-up laminate 21A in which a number of build-up layers 21A₁-21A₆ are laminated, and solder resist layers 21B and 21C are formed respectively on the top and bottom surfaces of the resin build-up laminate 21A. Each of the build-up layers 21A₁-21A₆ is formed with Cu interconnection patterns 21Ac in the form of a six-layer stack of via pattern of a diameter of 40 μm and a line-and-space pattern of 30 μm/30 μm, for example. Thereby, a part of the Cu interconnection patterns 21Ac forms a through-via 21At that penetrates through the resin build-up laminate 21A.

With the semiconductor device 20 of the present embodiment, it should be noted that a composite material, in which a glass cloth 21G of the elastic modulus of 40 GPa for example is impregnated by a solder resist resin compound, is used for the solder resist layers 21B and 21C. Thereby, the solder resist layers 21B and 21C has an elastic modulus of 10-30 GPa, such as 15 GPa, in spite of the fact that the solder resist resin composition itself is a conventional one characterized by the elastic modulus of 2-3 GPa.

With the construction of FIG. 3, such rigid solder resist layers 21B and 21C are provided to the front surface and the rear surface of the resin build-up stack 21A of small elastic modulus, and the resin build-up laminate 21A is reinforced mechanically from the front side and the rear side. Thereby, warp or deformation of the substrate is suppressed effectively.

Further, there is formed an array of electrode pads 21b in the solder resist layer 21B in contact with the interconnection pattern 21Ac in the build-up layer 21A₆, and electrode pads 21c are formed similarly in the solder resist layer 21C. Thereby, the solder resist layers 21B and 21C performs the function of conventional solder resist film such as prevention of the solder bridging, reduction solder pickup, prevention of contamination of the solder pot, protection of the substrate at the time of the assembling, elimination of oxidation or corrosion of the copper interconnection pattern, elimination of electromigration, and the like. Thus, any of an epoxy resin, an acrylic ester resin or epoxy acrylate, which are used for conventional solder resist, is used for the resin material constituting the solder resist layers 21B and 21C.

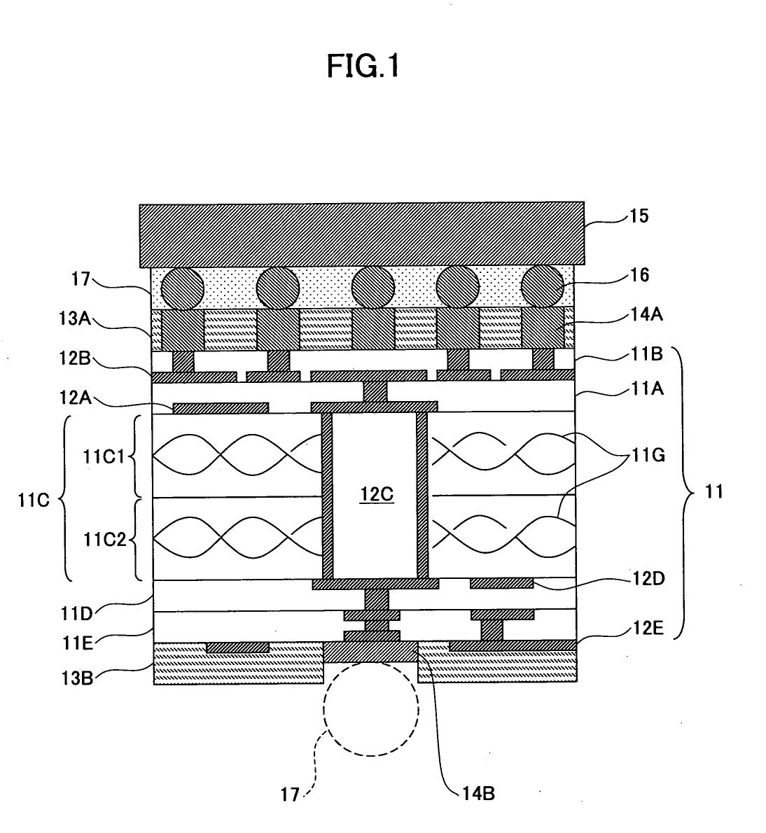

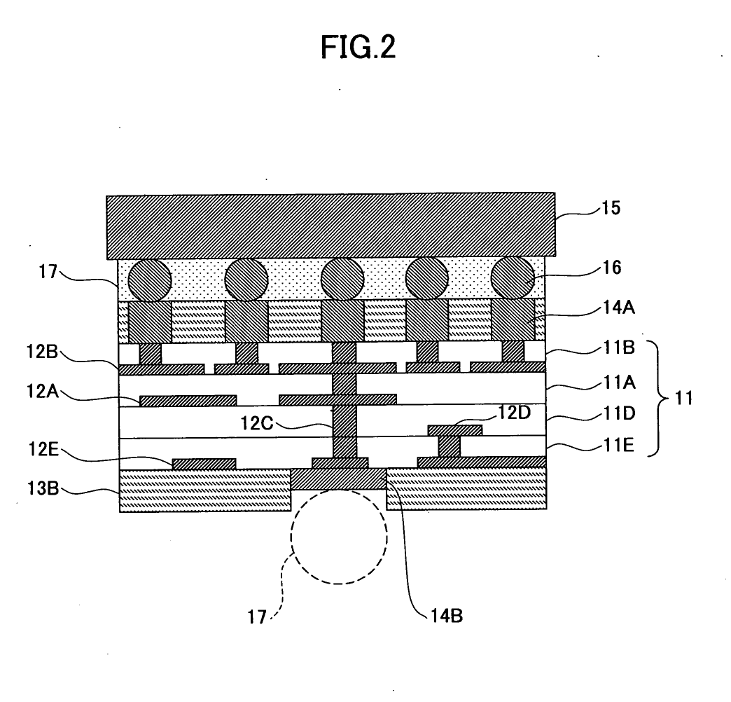

While it is conceivable to use a prepreg containing the glass cloth used for the core materials 11C₁ and 11C₂ explained with reference to FIG. 1 also for the solder resist layers 21B and 21C, these materials, designed for the core layers, cannot perform the function of solder resist satisfactorily when used for the solder resist layers 21B and 21C.

Thus, it is difficult to dispose a conventional core material on the outermost surface of the multilayer resin substrate.

For the glass cloth 21G, it is preferable to use a flat glass cloth of high open fabric of high density.

Further, the semiconductor chip 22 is flip-chip mounted on the electrode pads 21b, and solder bumps 23 are formed on the electrode pads 21c for mounting to a circuit substrate.

With the multilayer interconnection substrate 21 of such a structure, the solder resist layers 21B and 21C containing the glass cloth are located outside the signal path formed in the resin build-up laminate 21A, and thus, no increase of inductance is caused in the signal path with such solder resist layers 21B and 21C. While the resist films 21B and 21C may have an increased thickness as compared with conventional solder films due to the impregnation of glass cloth, no substantial effect is caused in the transmission characteristics of signals through the substrate.

While it is preferable that the solder resist layers 21B and 21C have a thickness of 40-60 μm generally equal to the thickness of the core layers 11C₁ and 11C₂ of the construction of FIG. 1, no adversary effect is caused in the electric characteristics of the multilayer interconnection substrate 21 as long as the thickness does not exceed a thickness approximately equal to ten times as large as the thickness of the core layer.

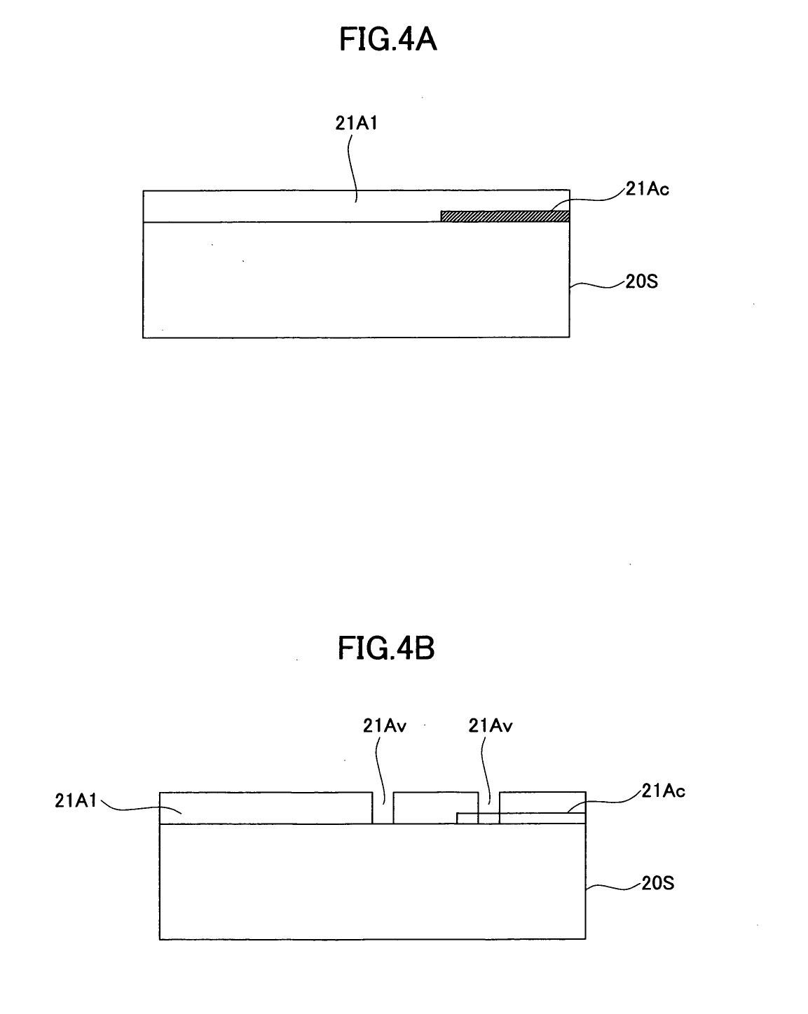

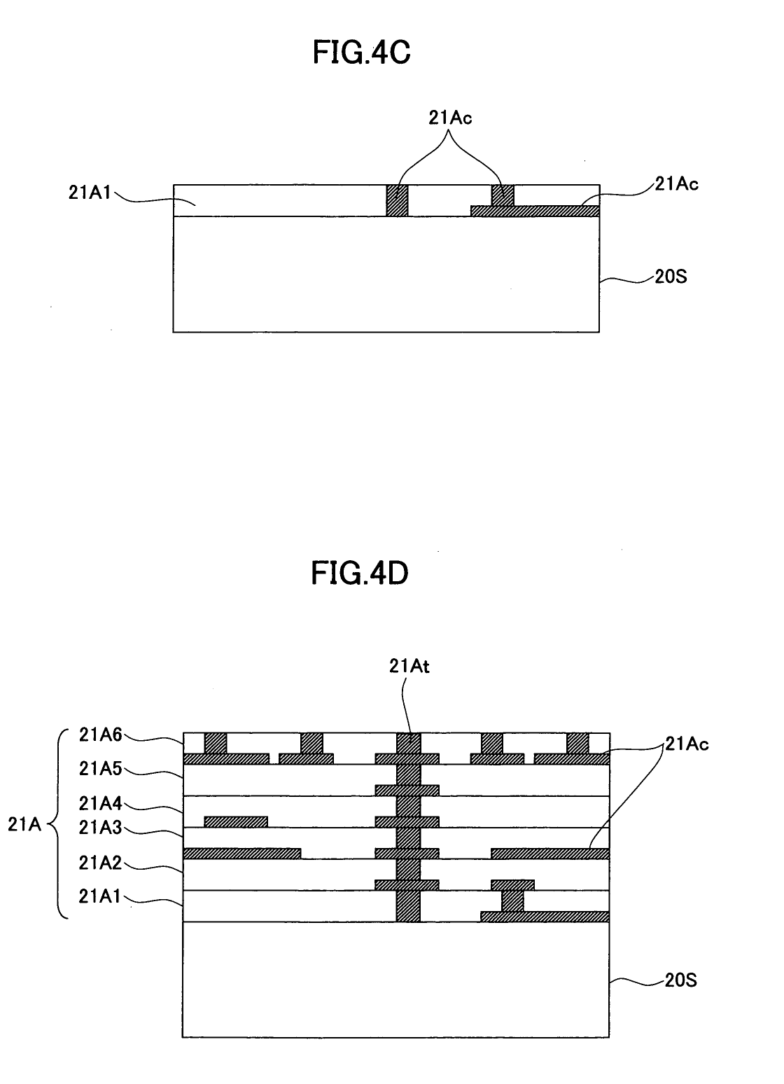

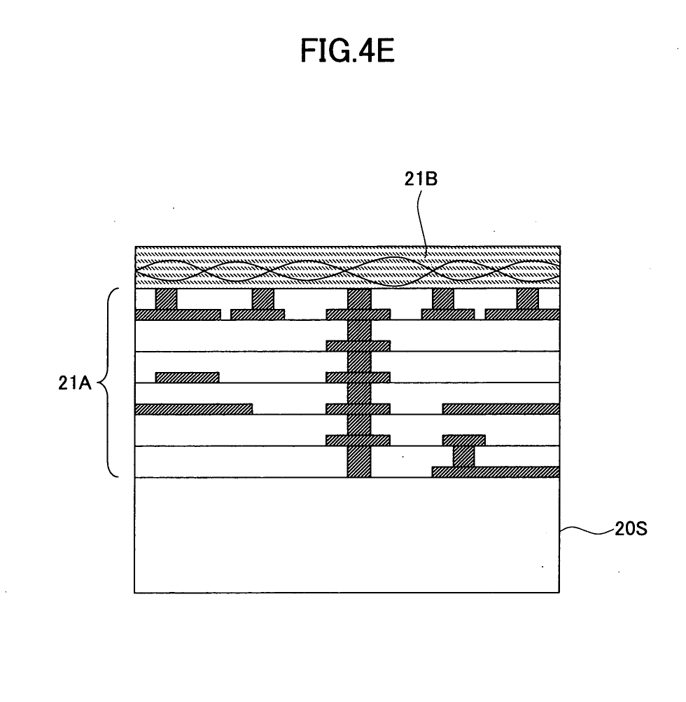

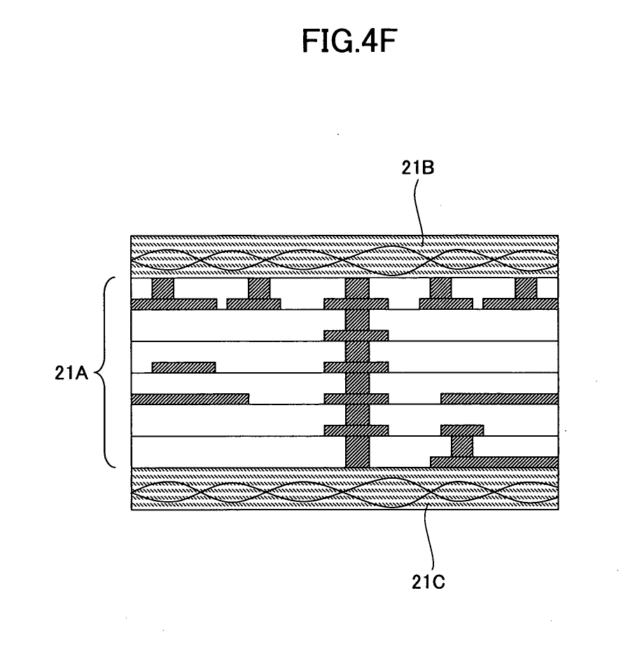

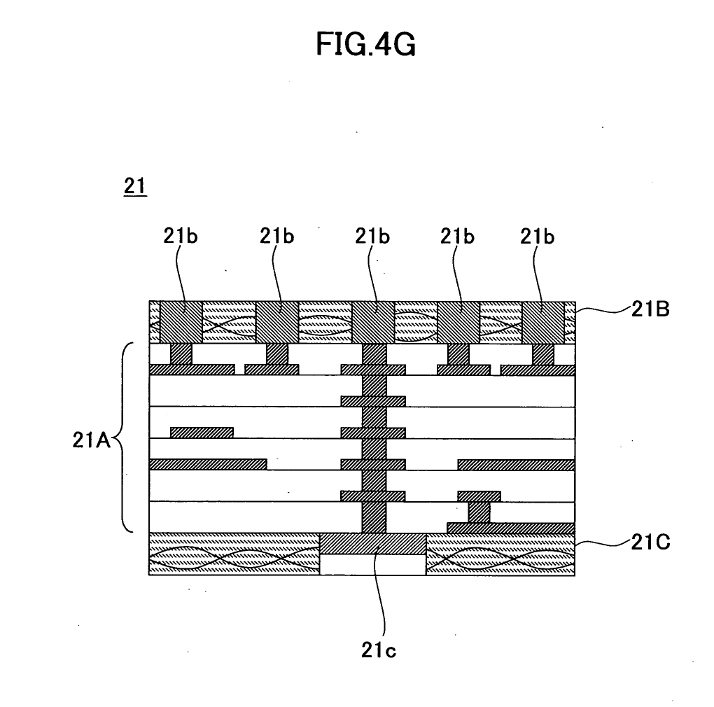

Next, the manufacturing process of the multilayer interconnection substrate 21 of the FIG. 3 will be explained with reference to FIGS. 4A-4H.

Referring to FIG. 4A, the Cu interconnection pattern 21Ac of the first layer is formed on a support member 20S of Cu or Cu alloy, and a build-up insulation film 21A₁ of the first layer is formed by laminating a resin layer marketed by Tomoegawa Paper Co. Ltd under the trade name TLF-30 by a vacuum lamination process.

Next in the process of FIG. 4B, an opening 21Av is formed in the build-up insulation film 21A, by a CO₂ laser drilling process, and a Cu seed layer (not shown) is formed on the entire surface of the structure of FIG. 4B by using a non-electrolytic plating liquid marketed from Rohm and Haas Company.

Further, in the step of FIG. 4C, a resist pattern is formed on the Cu seed layer by using Photec RY-3229 (trade name of Hitachi Chemical Co., Ltd.), and the openings 21Av are filled with a Cu layer by conducting an electrolytic plating process of Cu while using the resist pattern as a mask. With this, Cu interconnection patterns 21Ac are formed. It should be noted that FIG. 4C is shows the state in which the resist pattern and unnecessary Cu seed layer are removed after the formation of the Cu layer by the electrolytic plating process.

Further, by repeating the process of FIGS. 4A-4C, the insulation films 21A₁-21A₆ are laminated, and the resin build-up laminate 21A that includes the copper interconnection patterns 21Ac and the through-via 21At is formed as shown in FIG. 4D.

Next, in the step of FIG. 4E, the solder resist layer 21B is formed on the resin-buildup laminate 21A, wherein the solder resist layer 21B is formed of a glass cloth impregnated with a solder resist, wherein a solder resist marketed by Taiyo Ink MFG. Co., Ltd. under the trade name PSR-4000SP is used for this purpose. For the glass cloth, it is possible to use a high open fabric glass cloth provided from Asahi Fiberglass Co., Ltd., under the product name of High-Open Fabric Flat Roving Glass.

Further, in the step of FIG. 4F, the support member 20S is removed by etching and the solder resist layer 21C is formed on the bottom surface of the resin build-up laminate 21A similarly to the solder resist layer 21B.

Further, in the step of FIG. 4G, openings are formed in the solder resist layer 21B by laser drilling process in correspondence to the underlying interconnection pattern 21Ac or the through-via 21At, and the electrode pad 21b is formed in such an opening. Further, the electrode pad 21c is formed in such an opening.

The multilayer interconnection substrate 21 thus formed is subjected to measurement of warp. It was confirmed that the warp is suppressed successfully to about 50 μm in the case the substrate has a size of 4 cm for each edge. Particularly, it was confirmed that the warp is suppressed to about 20 μm in the region having a size of 2 cm for each edge where the semiconductor chip 22 is mounted. Thus, it was confirmed that it is possible to mount a semiconductor chip 22 on such a multilayer interconnection substrate 21 without using a stiffener.

Further, thermal cycling test was conducted for the structure in which the semiconductor chip 22 is flip-chip mounted on the multilayer interconnection substrate 21 thus formed in the state that a commonly used underfill resin (product name CRP-40753S3 of Sumitomo Bakelite Co., Ltd.) having an elastic modulus of 10 GPa is provided for the underfill resin layer 22B filling the gap between the semiconductor chip 22 and the substrate 21. The thermal cycling test was repeated for 300 times between −10° C. and 100° C. As a result, it was confirmed that there is caused no failure such as exfoliation or disconnection of electric contact between the semiconductor chip and the multilayer resin substrate 21.

Further, measurement was conducted for the warp in the state after the semiconductor chip 22 is mounted, and it was confirmed that the warp is 100 μm or less in the substrate having a size of 4 cm for each edge and that there is caused no detachment or disconnection of via-contact.

Here, it should be noted that the underfill resin layer 22B may or may not be added with filler particles.

In the comparative experiment in which the same solder resist material PSR-4000SP of Taiyo Ink MFG. Co. Ltd. is used in the construction of FIG. 3 but without impregnation of the glass cloth, it was observed that the magnitude of the warp increases from the value of 50 μm for the case the glass cloth is impregnated, to 300 μm for the substrate having the size of 4 cm for each edge. With regard to the chip mounting area of the size of 2 cm for each edge, it was confirmed that the warp increases from 20 μm to about 100 μm, while such large warp does not allow mounting of the semiconductor chip 22 on the substrate without use of a stiffener on the substrate.

Thus, in another comparative experiment, the multilayer resin interconnection substrate of the foregoing comparative experiment was provided with a Cu stiffener of the thickness of 1 mm along the periphery thereof. With this, the warp of the substrate was suppressed to about 100 μm. Further, the semiconductor chip 22 was mounted similarly by using the underfill resin, and thermal cycling test was conducted for 300 times between −10° C. and 100° C. In this comparative experiment, it was confirmed that there is caused disconnection between the substrate and the chip.

Further, warp of the substrate was measured in the state that the semiconductor chip is mounted, and it was observed that the warp reaches as much as 300 μm in this comparative experiment and that the semiconductor chip is detached and disconnection is caused in the through-via.

In this way, the present invention can effectively suppress the warp or deformation of the coreless multilayer resin substrate by mechanically reinforcing the solder resist layers provided at the outermost surfaces of the substrate with a glass cloth.

Further, it should be noted that the mechanical reinforcing of the multilayer resin substrate by the solder resist layer containing glass cloth is not limited to the coreless substrate but is effective also in the substrate of FIG. 1 having the core part in the event the thickness of the substrate is 500 μm or less and warp or deformation becomes a serious problem.

Because the solder resist layers 21B and 21C of the present invention contains the glass cloth, the drilling process of these layers is conducted by the laser beam process. Thus, there is no need that the solder resist layer has photosensitivity. This, however, does not mean that conventional photosensitive solder resist cannot be used with the present invention. In fact, the solder resist used with the embodiment of the present invention (PSR-4000SP) of Taiyo Ink MFG. Co. Ltd.) is a photosensitive solder resist.

Further, the present invention is not limited to the embodiments explained heretofore, but various variations and modifications may be made without departing from the scope of the invention.

What is claimed is:

1. A multilayer interconnection substrate, comprising:
a resin laminated structure in which plural build-up layers are laminated, each of said plural build-up layers comprising an insulation layer and an interconnection pattern; and
first and second solder resist layers provided on a top surface and a bottom surface of said resin laminated structure,
wherein each of said first and second solder resist layers includes therein a glass cloth.

2. The multilayer interconnection substrate as claimed in claim 1, wherein each of said first and second solder resist layers has an elastic modulus larger than an elastic modulus of said resin laminated structure.

3. The multilayer interconnection structure as claimed in claim 1, wherein each of said first and second solder resist layers has an elastic modules of 10-30 GPa.

4. The multilayer interconnection structure as claimed in claim 1, wherein each of said first and second solder resist layers has a thickness of 30-60 μm.

5. The multilayer interconnection substrate as claimed in claim 1, wherein said multilayer interconnection substrate has a thickness from a surface of said first solder resist layer to a surface of said second solder resist layer of 500 μm or less.

6. The multilayer interconnection substrate as claimed in claim 1, wherein said first and second solder resist layers are formed with respective electrode pads.

7. The multilayer interconnection substrate as claimed in claim 1, wherein said glass cloth comprises a highly opened fabric cloth.

8. A semiconductor device, comprising:
a multilayer interconnection substrate; and
a semiconductor chip mounted upon said multilayer interconnection substrate in a face-down state,
said multilayer interconnection substrate comprising:
a resin laminated structure in which plural build-up layers are laminated, each of said plural build-up layers comprising an insulation layer and an interconnection pattern;
first and second solder resist layers provided on a top surface and a bottom surface of said resin laminated structure, each of said first and second solder resist layers including therein a glass cloth; and
an electrode pad formed to said of said first and second solder resist layers.

9. The semiconductor device as claimed in claim 8, wherein each of said first and second solder resist layers has an elastic modulus larger than an elastic modulus of said resin laminated structure.

10. The semiconductor device as claimed in claim 8, wherein each of said first and second solder resist layers has an elastic modulus of 10-30 GPa.

11. A solder resist, comprising:
a layer having a solder resist resin composition; and
a glass cloth impregnated in said layer of said solder resist resin composition.

12. The solder resist as claimed in claim 11, wherein said solder resist resin composition comprises any of an epoxy resin, an acrylic ester resin, and epoxy acrylate.
